(19) United States
(12) Patent Application Publication
(10) Pub. No.: US 2025/0098247 A1
(43) Pub. Date: Mar. 20, 2025

(54) SEMICONDUCTOR STORAGE DEVICE

(71) Applicant: Kioxia Corporation, Tokyo (JP)

(72) Inventor: Tomohiro KOSUGI, Yokkaichi Mie (JP)

(21) Appl. No.: 18/883,483

(22) Filed: Sep. 12, 2024

(30) Foreign Application Priority Data
Sep. 15, 2023 (JP) 2023-150162

(51) Int. Cl. H01L 29/04; H01L 29/16; H10B 43/30

(52) U.S. Cl. CPC H10D 62/40; H10B 43/30; H10D 62/402; H10D 62/83

(57) ABSTRACT

According to one embodiment, a semiconductor storage device has a laminated body comprising conductive layers alternating with insulating layers in a first direction. A column extends into the laminated body and includes a first polycrystalline semiconductor film extending along the column in the first direction and a first insulating film extending along the column in the first direction. The first insulating film is between the conductive layers and the first polycrystalline semiconductor film. The first polycrystalline semiconductor film includes a first section corresponding in position along the first direction to an uppermost conductive layer among the conductive layers in the laminated body and a second section that is between the first section and a substrate in the first direction. An average grain diameter of the first section is smaller than an average grain diameter of the second section.

### CROSS-REFERENCE TO RELATED APPLICATIONS

This application is based upon and claims the benefit of priority from Japanese Patent Application No. 2023-150162, filed Sep. 15, 2023, the entire contents of which are incorporated herein by reference.

### FIELD

Embodiments described herein relate generally to a semiconductor storage device.

### BACKGROUND

There is a semiconductor storage device that includes a laminated body comprising a plurality of conductive layers with insulating layers in between otherwise adjacent conductive. A polycrystalline semiconductor column or pillar extends into the laminated body through the layers. Memory cells are formed at the intersecting positions where the conductive layers intersect with the polycrystalline semiconductor column or pillar. It is desirable that such a semiconductor storage device have improved reliability in operations.

### BRIEF DESCRIPTION OF THE DRAWINGS

FIG. 1 is a cross-sectional view illustrating a configuration of a semiconductor storage device according to an embodiment.

FIG. 2 is a block diagram schematically illustrating a semiconductor storage device according to an embodiment.

FIG. circuit diagram 3 is a illustrating a configuration of a memory cell array in an embodiment.

FIG. 4 is a cross-sectional view illustrating a configuration of the memory cell array in an embodiment.

FIG. 5 is a cross-sectional view illustrating a configuration of a memory cell in an embodiment.

FIG. 6 illustrates distributions of impurity concentration in a semiconductor film of an embodiment.

FIG. 7 to FIG. 16 are a cross-sectional views illustrating aspects of a manufacturing method of a semiconductor storage device according to an embodiment.

FIG. 17 is a cross-sectional view illustrating aspects of a manufacturing method of a semiconductor storage device according to a modification of an embodiment.

FIG. 18 is a cross-sectional view illustrating aspects of a manufacturing method of a semiconductor storage device according to a modification of an embodiment.

### DETAILED DESCRIPTION

An object of an embodiment is to provide a semiconductor storage device having improved reliability of operation.

In general, according to one embodiment, a semiconductor storage device includes a laminated body on a substrate. The laminated body includes conductive layers alternating with insulating layers in a first direction. A column extends into the laminated body in the first direction. The column includes a first polycrystalline semiconductor film extending along the column in the first direction and a first insulating film extending along the column in the first direction. The first insulating film is between the conductive layers and the first polycrystalline semiconductor film. The first polycrystalline semiconductor film includes a first section corresponding in position along the first direction to a first conductive layer among the conductive layers in the laminated body that is a farthest layer from the substrate in the first direction and a second section between the first section and the substrate in first direction. An average grain diameter of the first section is smaller than an average grain diameter of the second section.

A semiconductor storage device according to certain example embodiments will be described with reference to accompanying drawings. These example embodiments are not intended to limit the present disclosure.

### Embodiment

The semiconductor storage device according to one embodiment includes a plurality of conductive layers alternating with insulating layers in a stacking or lamination direction. The conductive layers and the insulating layers stacked on each other form what may be called a stacked body, a laminate body, or a laminated body. A semiconductor film extends into the stacked body in the laminate direction as a column, pillar, or tube. Memory cells are formed at the positions (the intersecting positions) where one of conductive layers intersects with the semiconductor film (column, pillar, or tube). The semiconductor film or portions thereof may be a polycrystalline film.

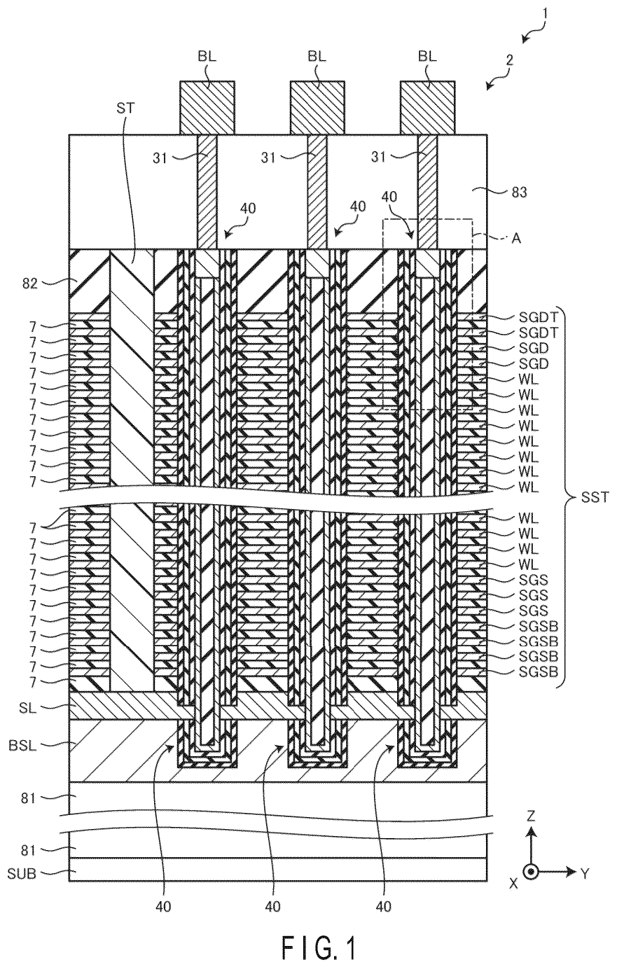

The semiconductor storage device 1 has a configuration as illustrated in FIG. 1. FIG. 1 is a cross-sectional view illustrating a general configuration of the semiconductor storage device 1.

In the following description, for convenience the X-direction is designated as a direction in which a word line WL extends, and the Y-direction is designated as a direction in which a bit line BL extends. The Z-direction is designated as a direction orthogonal to the surface of the substrate SUB.

As illustrated in FIG. 1, select gates SGS, select gates SGSB, word lines WL, select gates SGDT, and select gates SGD are included in the semiconductor storage device 1. The select gate SGS is above a source line SL with an insulating layer 7 in between. In the example of FIG. 1, four (4) layers of select gates SGSB are provided and three (3) layers of select gates SGS are provided. A word line WL is laminated above the uppermost layer of the select gates SGS with an insulating layer 7 in between. In the example of FIG. 1, multiple layers of word lines WL are provided along the Z-direction in an alternating manner with insulating layers 7. The select gates SGD, SGDT are laminated above the uppermost layer of the word lines WL with insulating layers 7 in between. In the example of FIG. 1, two (2) layers of select gates SGD are provided and two (2) layers of select gates SGDT are provided. The select gates SGSB, SGS, the word lines WL, and the select gates SGD, SGDT each have a plate shape extending in the X-direction and the Y-direction.

In the example of FIG. 1, the select gates SGDT, SGD, the word lines WL, and the select gates SGS, SGSB are divided and the separated portions insulated from each other in the Y-direction by a slit ST. In some examples, the source line may have a two-layer structure. Here, a two-layer structure for the source line includes a laminate of a source line BSL and a source line SL. The source line BSL and the source line SL are laminated on the +Z side of the substrate SUB with an interlayer dielectric 81 in between the source line BSL and the substrate SUB. The source line BSL is in contact with a surface of the source line SL on the −Z side and serves to lower the electrical resistance of the source line SL. The slit ST is provided on the +Z side of the source line SL and extends in the X-direction and the Z-direction.

The select gate SGD can be divided, for example, by a dividing film in the Y-direction. The dividing film is provided above the word line WL (+Z side) and extends in the X-direction and the Z-direction.

The substrate SUB is, for example, a silicon substrate. The select gate SGS, the word line WL, and the select gate SGD can be a metal layer comprising, for example, tungsten (W). The insulating layer 7 and the interlayer dielectric 81 are an insulator material such as silicon oxide or the like.

The semiconductor storage device 1 includes a plurality of columnar bodies 40. The columnar body 40 extends through the select gate SGS, the word lines WL, and the select gate SGD in the Z-direction, which is a laminate direction thereof. The semiconductor storage device 1 further includes a plurality of bit lines BL provided above the select gate SGD.

Each columnar body 40 is electrically connected to a bit line BL via a contact plug 31. For example, columnar bodies 40 that share a select gate SGD0 and columnar bodies 40 that share a select gate SGD1 are electrically connected to one bit line BL.

An interlayer dielectric 83 is provided between the upper end of the columnar body 40 and the bit line BL. An interlayer dielectric 82 is provided between the interlayer dielectric 83 and the select gate SGD. The contact plugs 31 pass through the interlayer dielectric 83. The contact plug 31 is connected between a semiconductor film portion of a columnar body 40 and to the bit line BL.

In the semiconductor storage device 1, the select gates SGD, the word lines WL, and the select gates SGS are each made of a conductive layer in the laminate body SST. The laminate body SST comprises alternately laminated conductive layers and insulating layers 7. The laminate body SST is formed on the +Z side of the source line SL. By the columnar bodies 40 passing through the laminate body SST, a three-dimensional array of memory cells (a memory cell array) is formed.

In other words, in the semiconductor storage device 1, a position where a word line WL (a conductive layer) intersects with a columnar body 40 functions as a memory cell, so that a memory cell array 2 in which a plurality of memory cells which are three-dimensionally arranged is formed. A position where a select gate SGS (a conductive layer) intersects with a columnar body 40 functions as a source-side select gate and a position where a select gate SGD (a conductive layer) intersects with a columnar body 40 functions as a drain-side select gate. In the semiconductor storage device 1, it is possible to increase memory capacity by increasing the number of layers of word lines WL in the laminate body SST without using finer patterning techniques.

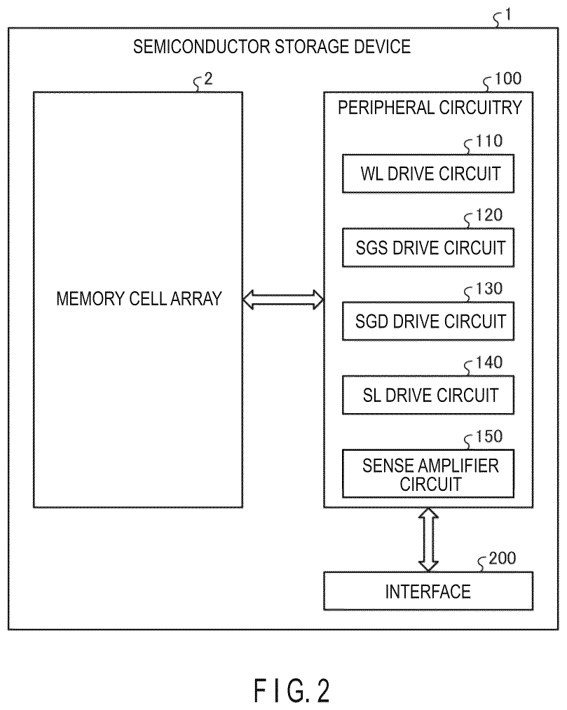

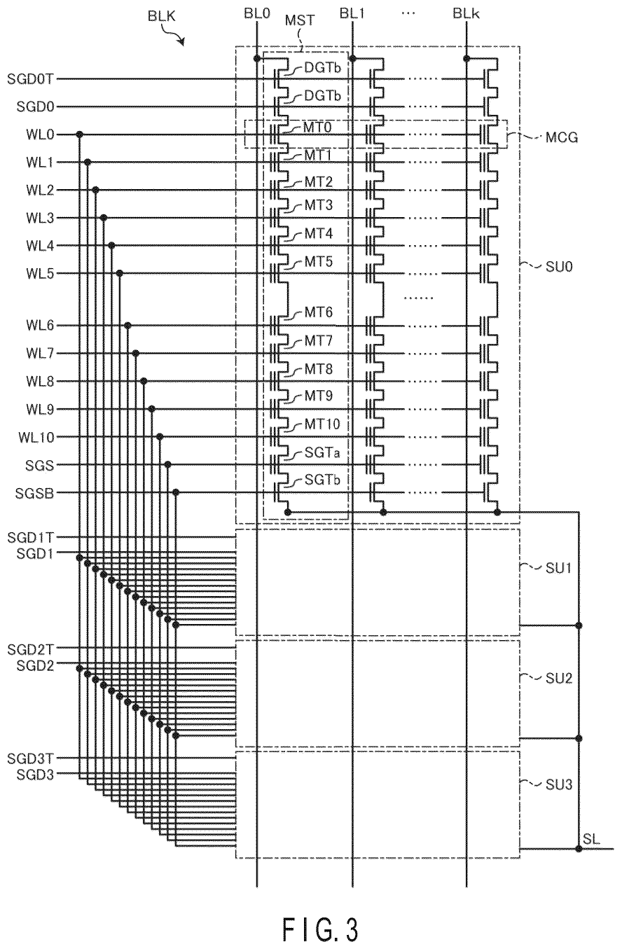

FIG. 2 is a block diagram illustrating a general configuration of the semiconductor storage device 1.

As illustrated in FIG. 2, the semiconductor storage device 1 includes the memory cell array 2, peripheral circuitry 100, and an interface 200. The peripheral circuitry 100 includes a WL drive circuit 110, an SGS drive circuit 120, an SGD drive circuit 130, an SL drive circuit 140, and a sense amplifier circuit 150.

The WL drive circuit 110 controls voltages applied to the word lines WL, and the SGS drive circuit 120 controls voltages applied to the select gates SGS, SGSB. The SGD drive circuit 130 controls voltages applied to the select gates SGD, SGDT, and the SL drive circuit 140 controls voltages applied to the source line SL. The sense amplifier circuit 150 controls voltages applied to the bit lines BL and also validates the data read from a selected memory cell.

The peripheral circuitry 100 controls the operations of the semiconductor storage device 1 based on instructions input from outside (for example, a memory controller of a memory system to which the semiconductor storage device 1 is incorporated) via the interface 200.

Next, a circuit configuration of the memory cell array 2 will be described with reference to FIG. 3. FIG. 3 is a circuit diagram illustrating a configuration of the memory cell array 2.

The memory cell array 2 includes a plurality of blocks BLK, each of which is a set (group) of memory cell transistors MT. Hereinafter, the memory cell transistors MT will be referred to more simply as memory cells MT.

Each block BLK includes a plurality of string units (string units SU0, SU1, SU2, SU3), each of which is a set of memory cells MT associated with the word lines WL and a bit line BL. Each of the string units SU0 to SU3 include a plurality of memory strings MST in which memory cells MT are connected in series. Note that there may be any number of memory strings MST in the string units SU0 to SU3.

The plurality of string units SU0, SU1, SU2, SU3 correspond to a plurality of select gates SGD0, SGD1, SGD2, SGD3 respectively and share the select gate SGS to function as a plurality of drive units in the block BLK. Each string unit SU is driven by a corresponding select gate SGD and select gate SGS. Each string unit SU also includes a plurality of memory strings MST.

Each memory string MST includes, for example, eleven (11) memory cells MT (MT0 to MT10) and select transistors DGT, SGT. The memory cell MT includes a control gate and a charge storage film and retains and stores data in a non-volatile manner. Then, the 11 memory cells MT are connected in series between a source of the select transistor DGT and a drain of the select transistor SGT. Note that the number of memory cells MT in the memory string MST is not limited to eleven (11) and the number may be greater than or less than eleven.

The gate of a select transistor DGTb in each of the string units SU0 to SU3 is connected to the respective one of select gates SGD0T to SGD3T. The gate of a select transistor DGTa in each of the string units SU0 to SU3 is connected to the respective one of select gates SGD0 to SGD3. In contrast, the gate of a select transistor SGTa in each string unit SU is commonly connected to, for example, the select gate SGS. The gate of a select transistor SGTb in each string unit SU is commonly connected to, for example, select gate SGSB.

The drain of the select transistor DGT in each memory string MST in each string unit SU is connected to the respective different one of bit lines BL0 to BLk (k is any integer not less than 2). Furthermore, the bit lines BL0 to BLk are commonly connected to one memory string MST in each string unit SU across a plurality of blocks BLK. Furthermore, the source of each select transistor SGT is commonly connected to the source line SL.

In other words, the string unit SU is a set of memory strings MST that are connected to different bit lines BL0 to BLk and connected to the same select gate SGD. Furthermore, each block BLK is a set of a plurality of string units SU0 to SU3 that have a common word line WL. Then, the memory cell array 2 is a set of a plurality of blocks BLK that have common bit lines BL0 to BLk.

Referring to a group of memory cells MT that share the word line WL as “memory cell group MCG”, the memory cell group MCG is the minimum unit of a set of memory cells MT that can be applied a predetermined voltage (for example, write voltage, read voltage) collectively via the word line WL.

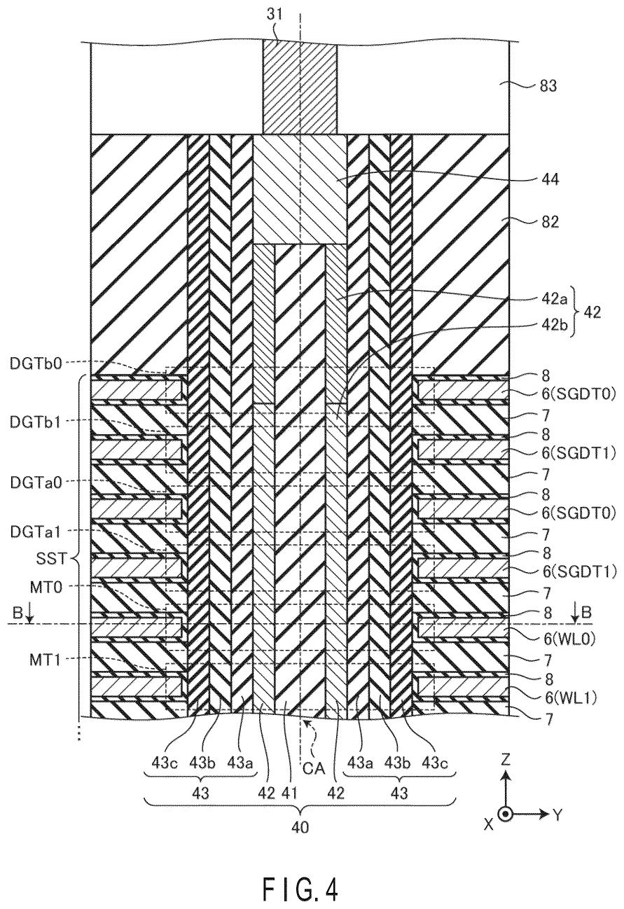

Next, a cross-sectional configuration of the memory cell array 2 will be described with reference to FIG. 4. FIG. 4 is a YZ-sectional view illustrating the configuration of the memory cell array 2 and is an enlarged cross-sectional view of a portion A in FIG. 1.

In the semiconductor storage device 1, the source line SL (see FIG. 1) is disposed on the +Z side of the substrate SUB. The columnar bodies 40 are arranged in the XY-direction. Each columnar body 40 extends in the Z-direction and passes through the laminate body SST.

The columnar body 40 illustrated in FIG. 4 has a columnar shape that has a central axis CA along the Z-direction and has, for example, a substantially cylindrical shape. In FIG. 4, a portion near the −Z-side end in the columnar body 40 is illustrated. The columnar body 40 may have a tapered shape such that the diameter at the −Z-side end is smaller than the diameter at the +Z-side end. The columnar body 40 may have a bowing shape such that the diameter at the −Z-side end is smaller than the diameter at the +Z-side end and the diameter increases at a predetermined Z-position between the +Z-side end and the −Z-side end. The diameter at the −Z-side end of the columnar body 40 is smaller than the diameter at the +Z-side end of the columnar body 40.

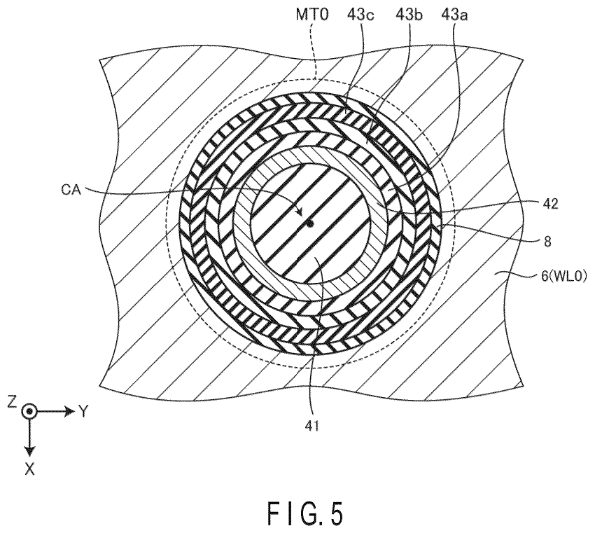

As illustrated in FIG. 4 and FIG. 5, the columnar body 40 includes a core member 41, a polycrystalline semiconductor film 42, and an insulating film 43 in order from the side of a central axis CA. The insulating film 43 is a multilayer film that includes an insulating film 43a, a charge storage film 43b, and an insulating film 43c in order from the side of a central axis CA. FIG. 5 is an XY-sectional view illustrating a configuration of the memory cell and illustrates a cross section taken along a line B-B in FIG. 4.

The core member 41 is disposed near the central axis CA of the columnar body 40 and has a substantially cylindrical shape extending along the central axis CA of the columnar body 40. The core member 41 may be made of a material, the principal constituent of which is an insulator (for example, semiconductor oxide such as silicon oxide).

The polycrystalline semiconductor film 42 is disposed so as to surround the outside of the core member 41 and has a substantially hollow-cylindrical shape extending along the central axis CA of the columnar body 40. The polycrystalline semiconductor film 42 may be made of a material, the principal constituent of which is a semiconductor (for example, polysilicon) that contains substantially no impurity.

The insulating film 43a is disposed so as to surround the outside of the polycrystalline semiconductor film 42 and has a substantially hollow-cylindrical shape extending along the central axis CA of the columnar body 40. The insulating film 43a may be made of a material, the principal constituent of which is an oxide (for example, silicon oxide or silicon oxynitride).

The charge storage film 43b is disposed so as to surround the outside of the insulating film 43a and has a substantially hollow-cylindrical shape extending along the central axis CA of the columnar body 40. The charge storage film 43b may be made of a material, the principal constituent of which is a nitride (for example, silicon nitride).

The insulating film 43c is disposed so as to surround the outside of the charge storage film 43b and has a substantially hollow-cylindrical shape extending along the central axis CA of the columnar body 40. The insulating film 43c may be made of a material, the principal constituent of which is oxide (for example, silicon oxide, metal oxide, or a lamination thereof). In this way, an ONO three-layer structure in which the charge storage film 43b is sandwiched between a pair of insulating films 43a, 43c may be formed.

The insulating film 8 surrounds the insulating film 43c from outside in the XY-direction and extends so as to cover a surface of the conductive layer 6 on the +Z side, a surface on the side of the columnar body 40, and a surface of the conductive layer 6 on the −Z side, so that a substantially hollow disk shape that has an axis along the Z-direction is formed. The insulating film 8 may be formed of an insulator such as aluminum oxide. In the following, illustration and description of the insulating film 8 may be omitted for simplicity.

As illustrated in FIG. 4, the columnar body 40 further includes a polycrystalline semiconductor film 44.

The polycrystalline semiconductor film 44 is disposed near the central axis CA of the columnar body 40 and has a substantially cylindrical shape extending along the central axis CA of the columnar body 40. The outer diameter of the polycrystalline semiconductor film 44 corresponds to the outer diameter of the polycrystalline semiconductor film 42. The polycrystalline semiconductor film 44 is disposed between the core member 41 and the polycrystalline semiconductor film 42 on one side and the contact plug 31 on the other side. An end face of the polycrystalline semiconductor film 44 on the −Z side covers an end of the core member 41 on the −Z side and an end of the polycrystalline semiconductor film 42 on the −Z side, and an end face thereof is in contact with the contact plug 31.

The polycrystalline semiconductor film 42 of the columnar body 40 is connected to the source line SL (see FIG. 1) on its −Z side (lower end) and connected to the bit line BL (see FIG. 1) on its +Z side (upper end) via the polycrystalline semiconductor film 44 and the contact plug 31. That is, the polycrystalline semiconductor film 42 of the columnar body 40 includes a channel region (active region) in the memory string MST.

In the laminate body SST, the conductive layers 6 and the insulating layers 7 are laminated in an alternating and repetitive manner. Each conductive layer 6 extends in the XY-direction in a plate shape. Each conductive layer 6 may be made of a material, the principal constituent of which is a conductor (for example, metal such as tungsten). A surface on the +Z side, a surface on the −Z side, and a surface facing the columnar body 40 of each conductive layer 6 may be covered with the insulating film 8. The insulating film 8 may have a composition different from the insulating film 43c. The insulating film 8 may be made of a material, the principal constituent of which is an insulator (for example, metal oxide such as aluminum oxide, zirconium oxide, and hafnium oxide). Each insulating layer 7 extends in the XY-direction in a plate shape. Each insulating layer 7 may be made of a material, the principal constituent of which is an insulator (for example, semiconductor oxide such as silicon oxide).

In the laminate body SST, among a plurality of conductive layers 6 spaced apart from each other in the Z-direction the conductive layers 6 on the −Z side function as the select gates SGSB, SGS (see FIG. 1), the conductive layers 6 on the +Z side function as the select gates SGDT, SGD (see FIG. 1), and the conductive layers 6 therebetween function as word lines WL. FIG. 4 illustrates a configuration in which in the laminate body SST, from the −Z side, the conductive layer 6 of a select gate SGSB1, the conductive layer 6 of a select gate SGSB2, the conductive layer 6 of a select gate SGSB3, the conductive layer 6 of a select gate SGSB4, the conductive layer 6 of a select gate SGS1, the conductive layer 6 of a select gate SGS2, and the conductive layer 6 of a select gate SGS3 are laminated.

At a position where the conductive layer 6 of a select gate SGDT0 intersects with the polycrystalline semiconductor film 42, a select transistor DGTb0 is formed. At a position where the conductive layer 6 of a select gate SGDT1 intersects with the polycrystalline semiconductor film 42, a select transistor SGTb1 is formed.

At a position where the conductive layer 6 of the select gate intersects SGD0 with the polycrystalline semiconductor film 42 and the charge storage film 43b, a select transistor DGTa0 is formed. At a position where the conductive layer 6 of the select gate intersects SGD1 with the polycrystalline semiconductor film 42, a select transistor DGTa1 is formed.

At a position where the conductive layer 6 of a word line WL0 intersects with the polycrystalline semiconductor film 42 and the charge storage film 43b, a memory cell MT0 is formed. At a position where the conductive layer 6 of a word line WL1 (see FIG. 1) intersects with the polycrystalline semiconductor film 42 and the charge storage film 43b, a memory cell MT1 (see FIG. 3) is formed. At a position where the conductive layer 6 of a word line WL10 intersects with the polycrystalline semiconductor film 42 and the charge storage film 43b, a memory cell MT10 is formed.

At a position where the conductive layer 6 of the select gate SGS (see FIG. 1) intersects with the polycrystalline semiconductor film 42, a select transistor SGTa (see FIG. 3) is formed.

At a position where the conductive layer 6 of the select gate SGSB (see FIG. 1) intersects with the polycrystalline semiconductor film 42, a select transistor SGTb (see FIG. 3) is formed.

Note that, in the columnar body 40, at an intersecting position with the conductive layers 6 of the select gates SGD, SGDT, the charge storage film 43b and the insulating film 43c may be partially omitted.

As illustrated in FIG. 4, the polycrystalline semiconductor film 42 of each columnar body 40 includes a section 42a and a section 42b.

The section 42a is disposed so as to surround the outside of the core member 41 and has a substantially hollow-cylindrical shape extending along the central axis CA of the columnar body 40.

The section 42a corresponds in position to the uppermost conductive layer 6 in the laminate body SST (for example, conductive layer 6 of the select gate SGDT0). The uppermost conductive layer 6 on the +Z side of the conductive layers 6 can also be referred to as the conductive layer 6 that is the farthest layer from the substrate SUB (see FIG. 1) among the plurality of conductive layers 6.

The section 42a is a section in the polycrystalline semiconductor film 42 from the +Z-side end up of the polycrystalline semiconductor film 42 to a Z-position corresponding to the uppermost conductive layer 6. The Z-position corresponding to the uppermost conductive layer 6 may be a position between the +Z-side surface of the uppermost conductive layer 6 and the +Z-side surface of the second uppermost conductive layer 6.

The section 42a is in contact with the polycrystalline semiconductor film 44 on the +Z end and is in contact with the section 42b on the −Z end. The section 42a may be continuous with the section 42b on the −Z side.

The section 42b corresponds in position to the rest of the plurality of conductive layers 6 in the laminate body SST except for the uppermost conductive layer 6 on the +Z side (for example, the conductive layer 6 of the select gate SGDT1 to the conductive layer 6 of the select gate SGSB). The rest of the plurality of conductive layers 6 except for the uppermost conductive layer 6 on the +Z side can otherwise be referred to as two or more conductive layers 6 among the plurality of conductive layers 6 disposed between the substrate SUB (see FIG. 1) and the uppermost conductive layer 6 on the +Z side.

The section 42b is a portion of the polycrystalline semiconductor film 42 from the Z-position corresponding to the uppermost conductive layer 6 on the +Z side to the −Z-side end (lower end) of the polycrystalline semiconductor film 42.

The section 42b is in contact with the section 42a on the +Z end. The section 42b may be continuous with the section 42a.

The Z-height from the substrate SUB of the boundary between the section 42a and the section 42b may be located at a position between the Z-height from the substrate SUB of an upper surface (surface on +Z side) of the uppermost conductive layer 6 on the +Z side of a plurality of conductive layers 6 and the Z-height from the substrate SUB of an upper surface (surface on +Z side) of the second uppermost conductive layer 6 on the +Z side.

For example, the Z-height from the substrate SUB of a boundary between the section 42a and the section 42b may be substantially equal to the Z-height from the substrate SUB of a lower surface (surface on the −Z side) of f the uppermost conductive layer 6 on the +Z side of a plurality of conductive layers 6.

Each of the section 42a and the section 42b may be made of a material, the principal constituent of which is polycrystalline semiconductor (for example, polysilicon). The average grain diameter d1 of the section 42a is smaller than the average grain diameter d2 of the section 42b.

While the way of determining (measuring or evaluating) the average grain diameter is not particularly limited, the average grain diameter can be determined by using, for example, a flow particle image analyzer, a particle distribution measurement device incorporating a laser diffraction and scattering method, or the like may be used. Alternatively, the average grain diameter may be calculated from Transmission Electron Microscope (TEM) images by using the Intercept method (also referred to as Heyn method) or the Planimetric method (also referred to as Jeffries method).

Alternatively, the average grain diameter may be calculated by using Automated Crystal Orientation Mapping in TEM (ACOM-TEM) analysis. In the ACOM-TEM analysis, a semicircular sample is created by slicing the polycrystalline semiconductor film 42 in the direction perpendicular to the central axis CA, the sample is analyzed in a visual field of about 5 nm×5 nm, and the same grain diameters are determined if the azimuth angle difference is less than 5°. Under such conditions, an in-plane average grain diameter is obtained through the ACOM-TEM analysis. To calculate the average grain diameter, the grain diameter averaged in a visual field of about 5 nm×5 nm is used.

For example, crystal grains included in the polycrystalline semiconductor film 42 may have twins. When a twin boundary is not considered as a grain boundary, d calculated by the following Expression 1 may be designated as the average grain diameter, where N is the total number of particles and dᵢ is the grain diameter of an individual particle (equivalent circle diameter). In this case, the average grain diameter of the section 42a may be less than 80 nm, and the average grain diameter of the section 42b may be 80 nm or more.

$$\overline{d} = \frac{1}{N} {\sum }_{i = 1}^{N} {d}_{i} \qquad Expression 1$$

When a twin boundary is considered as a grain boundary, d calculated by the following Expression 2 may be designated as the average grain diameter, where N is the total number of particles and dᵢ′ is the grain diameter of an individual particle (equivalent circle diameter). In this case, the average grain diameter of the section 42a may be less than 30 nm, and the average grain diameter of the section 42b may be 30 nm or more.

$$\overline{d} = \frac{1}{N} {\sum }_{i = 1}^{N} {d}_{i}^{′} \qquad Expression 2$$

The average grain diameter d3 of the polycrystalline semiconductor film 44 may be larger than the average grain diameter d1 of the section 42a. The average grain diameter d3 of the polycrystalline semiconductor film 44 may be larger than the average grain diameter d2 of the section 42b.

In a write process of information to a memory cell MT, a write voltage is applied to the conductive layer 6 of a select word line WL, a transfer voltage is applied to the conductive layer 6 of a non-selected word line WL, a reference voltage is applied to the polycrystalline semiconductor film 42, a select voltage is applied to select gate lines SGD, SGDT of a select string, and a reference voltage is applied to select gate lines SGS, SGSB. The write voltage has a potential (for example, 20 V) for injecting charges (electrons) of the polycrystalline semiconductor film 42 to the charge storage film 43b. The transfer voltage has a potential (for example, 10 V) between the write voltage and the reference voltage. The reference voltage has a potential (for example, 0 V) that serves as a reference. The select voltage has a potential (for example, 2.5 V) that is enough for the select transistors DGTa, DGTb to turn on, and the reference voltage has a potential that is enough for the select transistors SGTa, SGTb to turn off. In this way, the charges are accumulated in the charge storage film 43b of the select memory cell MT at a position where the conductive layer 6 of the select word line WL intersects with the polycrystalline semiconductor film 42, so that the information is written in the select memory cell MT.

In a delete (data delete or data erase) process for information stored in a memory cell MT, a reference voltage is applied to the conductive layer 6 of each word line WL, a delete (erase) voltage is applied to the polycrystalline semiconductor film 42, a select voltage is applied to select gates SGS, SGSB, and an intermediate voltage is applied to select gates SGD, SGDT. The delete voltage has a potential (for example, 20 V) for injecting opposite charges (holes) of the polycrystalline semiconductor film 42 to the charge storage film 43b. The reference voltage has a potential (for example, 0 V) that serves as a reference level. The select voltage has a potential (for example, 20 V) that is enough for the select transistors SGTa, SGTb to turn off, and the intermediate voltage has a potential (for example, 5 V) between the delete voltage and the reference voltage. When controlled in this way, electron-hole pairs are generated due to the Gate Induced Drain Leakage (GIDL) near the drain of the select transistor SGTb, so that the opposite charges (holes) are injected from the polycrystalline semiconductor film 42 to the charge storage film 43b. In this way, the charges accumulated in the charge storage film 43b are deleted, so that the information in the memory cell MT is deleted.

In the delete process, the select transistor DGTb corresponding to the select gate SGDT handles the function of the GIDL generation, and the select transistor DGTa corresponding to the select gate SGD handles the function of electrically connecting and disconnecting the polycrystalline semiconductor film 42 to/from the bit line BL.

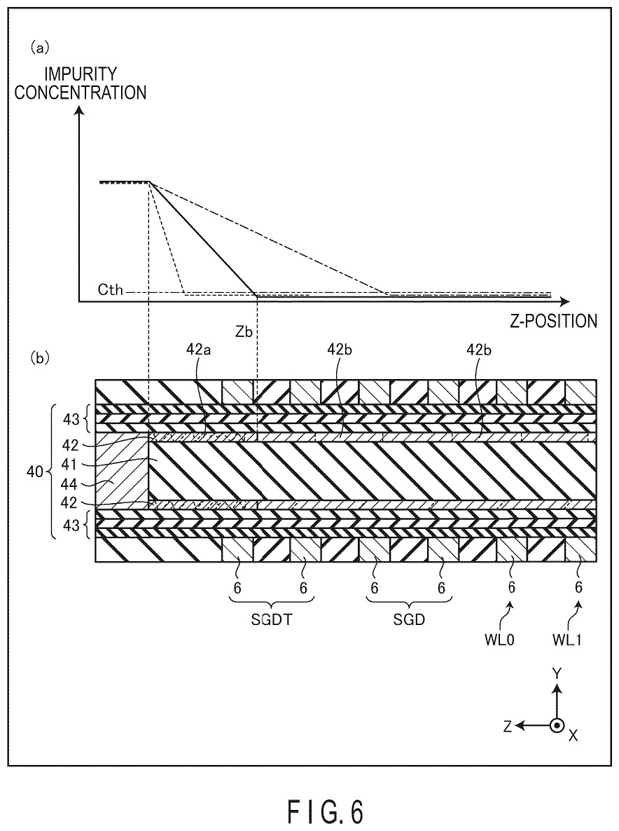

During manufacture of the semiconductor storage device 1, N-type impurities (for example, phosphorous) in the polycrystalline semiconductor film 44 are diffused into the polycrystalline semiconductor film 42. Correspondingly, as indicated by the solid line in a view (a) of FIG. 6, the concentration of N-type impurities in the polycrystalline semiconductor film 42 will be relatively higher in the section 42a than points beyond while impurity (dopant) concentration tends to decrease toward the Z-position Zb set as the nominal boundary between section 42a and section 42b.

FIG. 6 illustrates the distribution of impurity concentration in the polycrystalline semiconductor film 42. The view (a) of FIG. 6 illustrates the distribution of the concentration of N-type impurities in the polycrystalline semiconductor film 42 along the Z-direction. In view (a) of FIG. 6, the vertical axis indicates the N-type impurity concentration level and the horizontal axis indicates the Z-position along the polycrystalline semiconductor film 42. The view (b) of FIG. 6 illustrates a corresponding YZ-section including the polycrystalline semiconductor film 42 matching the horizontal axis (Z-position) in the view (a) of FIG. 6.

As depicted, in the present embodiment, average grain diameter in section 42a of the polycrystalline semiconductor film 42 is smaller than the average grain diameter in section 42b. Accordingly, the amount of diffusion of N-type impurities from the polycrystalline semiconductor film 44 can be properly controlled. The diffusion distance of N-type impurities into the polycrystalline semiconductor film 42 in the Z-direction from the polycrystalline semiconductor film 44 will be substantially equal to the interface position at the boundary (Z-position Zb) between section 42a and second 42b in the polycrystalline semiconductor film 42.

In other words, as indicated by the solid line in view (a) of FIG. 6, in the polycrystalline semiconductor film 42, N-type impurities may be at or greater than the threshold concentration Cth in the channel region of the select gate SGDT, while N-type impurities are kept below the threshold concentration Cth in the channel region of the select gate SGD. In this way, more efficient GIDL generation can be achieved at the select gate SGDT in a delete (data deletion) process while the select gate SGD can be properly turned on and off.

While the way of measuring the impurity (dopant) concentration is not particularly limited, a concentration measured by using, for example, a Secondary Ion Mass Spectrometry (SIMS) device may be adopted.

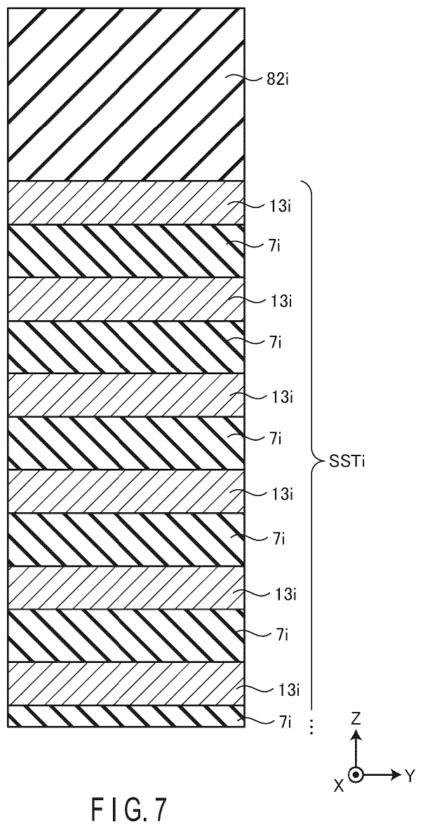

Next, a manufacturing method of the semiconductor storage device 1 will be described with reference to FIGS. 7 to 16 along with FIG. 4. FIGS. 7 to 16 are YZ-sectional views illustrating aspects of the manufacturing method of semiconductor storage device 1. While FIG. 4 is a YZ-sectional view illustrating a structure of the semiconductor storage device 1, it will also be referred to as a cross-sectional view illustrating aspects of a manufacturing method.

Initially at FIG. 7, transistors are first formed on the substrate SUB (see FIG. 1), contact plugs, wiring films, via plugs, and the like are formed on the substrate SUB, and an interlayer dielectric 81 is formed around or covering these components. In this way, the peripheral circuitry 100 is formed. The interlayer dielectric 81 is formed by depositing a material, the principal constituent of which is an insulator (for example, semiconductor oxide such as silicon oxide), on the +Z side of the substrate SUB.

The layer of the source line BSL is deposited on the +Z side of the interlayer dielectric 81. The layer of the source line BSL may be made of a material, the principal constituent of which is a semiconductor (for example, silicon) that contains N-type impurities (for example, phosphorous or arsenic).

The layer of the source line SL is deposited on the +Z side of the layer of source line BSL. The layer of the source line SL may be made of a material, the principal constituent of which is a semiconductor (for example, silicon) material that contains N-type impurities (for example, phosphorous or arsenic).

Insulating layers 7i and sacrificial layers 13i are then deposited alternately multiple times on the +Z side of the layer of the source line SL to form the laminate body SSTi. The insulating layer 7i may be made of a material, the principal constituent of which is an oxide (for example, silicon oxide). The sacrificial layer 13i may be made of a material, the principal constituent of which is a nitride (for example, silicon nitride). Each insulating layer 7i and each sacrificial layer 13i may be deposited to have substantially the same film thickness.

An interlayer dielectric 821 is deposited on the +Z side of the uppermost sacrificial layer 13i on the +Z side in the laminate body SSTi. The interlayer dielectric 82i may be made of a material, the principal constituent of which is oxide (for example, silicon oxide).

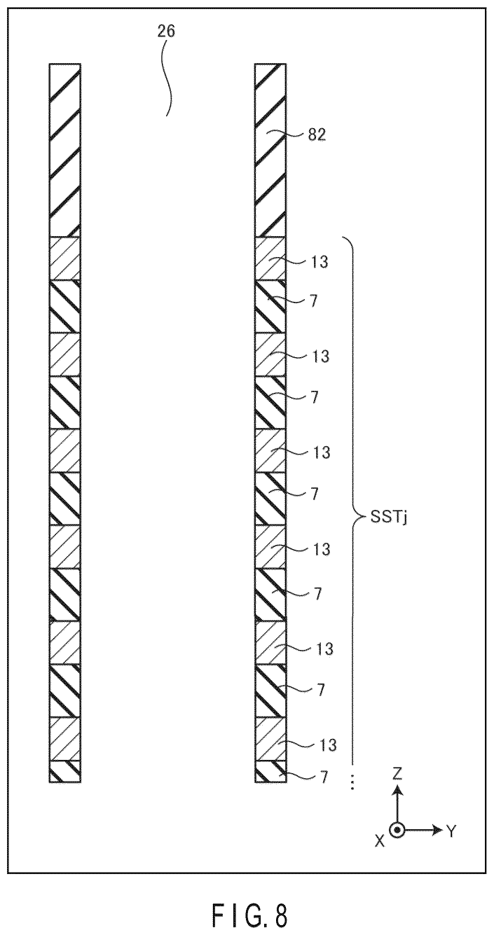

In FIG. 8, a resist pattern that has an opening at a position where a memory hole 26 is to be formed is formed on the laminate body. Using the resist pattern as a mask, anisotropic etching such as Reactive Ion Etching (RIE) method is performed to penetrate through the layers of the interlayer dielectric 82, the laminate body SSTj, and the source line SL (see FIG. 1) to form a memory hole 26 that reaches the layer of the source line BSL.

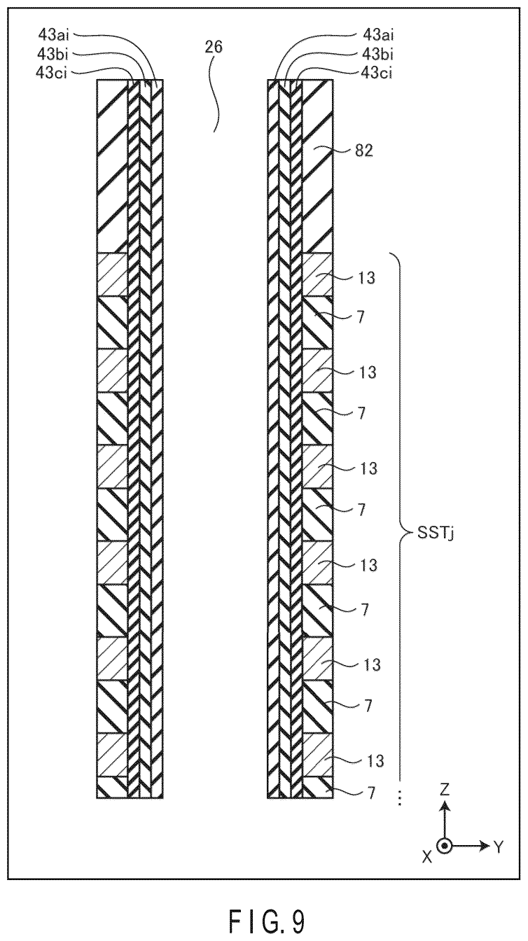

In FIG. 9, an insulating film 43ci, a charge storage film 43bi, and an insulating film 43ai (FIG. 4) are deposited on the side surface and the bottom surface of the memory hole 26 in order. The insulating film 43ci may be made of a material, the principal constituent of which is oxide (for example, silicon oxide, metal oxide, or a lamination thereof). The charge storage film 43bi may be made of a material, the principal constituent of which is a nitride (for example, silicon nitride). The insulating film 43ai may be made of a material, the principal constituent of which is an oxide (for example, silicon oxide or silicon oxynitride).

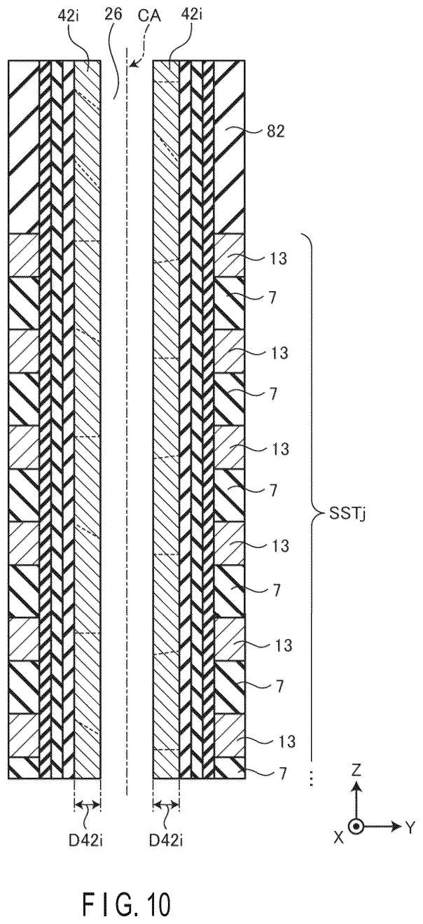

In FIG. 10, the polycrystalline semiconductor film 421 is deposited on the side surface and the bottom surface of memory hole 26. The polycrystalline semiconductor film 42i may be made of a material, the principal constituent of which is a polycrystalline semiconductor (for example, polysilicon) that contains substantially no impurity. The film thickness of the polycrystalline semiconductor film 421 is controlled by film-forming conditions or the like.

For example, the polycrystalline semiconductor film 42i is deposited under such film-forming conditions (for example, gas flow rate, film-forming time) such that the film thickness in a YZ-sectional view including the central axis CA is D42i.

The film thickness of the polycrystalline semiconductor film and the average grain diameter thereof are correlated with each other. There is a tendency that as the film thickness of the polycrystalline semiconductor film increases, the average grain diameter thereof also increases. The film thickness D42i of the polycrystalline semiconductor film 42i illustrated in FIG. 10 corresponds to the average grain diameter d2. The average grain diameter d2 will be the average grain diameter of the section 42b (see FIG. 4) to be formed in a subsequent step.

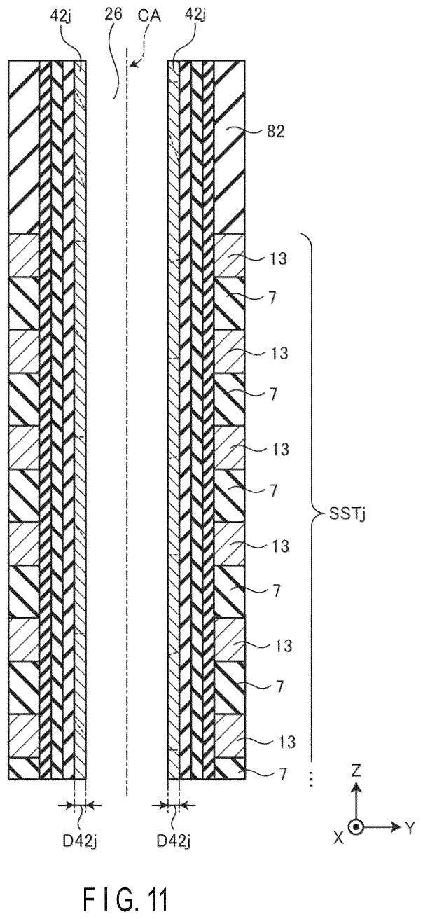

In FIG. 11, the polycrystalline semiconductor film 421 is thinned to be a polycrystalline semiconductor film 42j by an isotropic etching process such as wet etching. The amount of etching in the isotropic etching process can be controlled by the selected etching conditions or the like.

For example, the polycrystalline semiconductor film 42j is etched under etching conditions (for example, etching time) such that the film thickness in the YZ-sectional view including the central axis CA is D42j (<D42i).

The film thickness D42j of the polycrystalline semiconductor film 421 illustrated in FIG. 11 corresponds to the average grain diameter d1 (d1<d2). The average grain diameter d1 will be the average grain diameter of the section 42a (see FIG. 4) to be formed in a subsequent step.

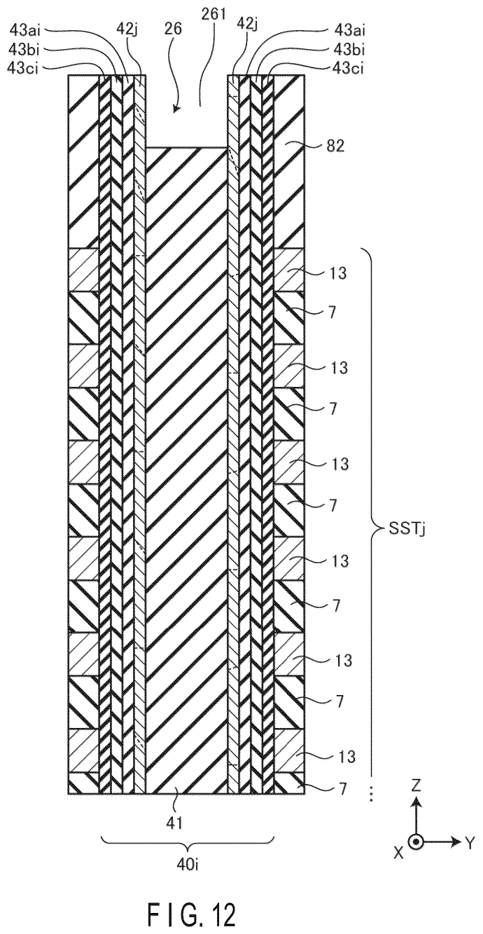

In FIG. 12, the core member 41 is buried in the memory hole 26. The core member 41 may be made of a material, the principal constituent of which is an insulator (for example, semiconductor oxide such as silicon oxide). In this way, the columnar body 40i (see FIG. 1) that penetrates through the laminate body SSTj and the layer of the source line SL and reaches the layer of the source line BSL.

The core member 41 may be buried in the memory hole 26 such that the Z-height of the end of the core member 41 on the +Z side is lower than the Z-height of the ends of the insulating film 43ci, the charge storage film 43bi, the insulating film 43ai, and the polycrystalline semiconductor film 42j on the +Z side. In this way, a recess 261 is formed, which is surrounded by the inner side surface of polycrystalline semiconductor film 42j and the +Z side surface of the core member 41. The recess 261 is a space that has a substantially cylindrical shape.

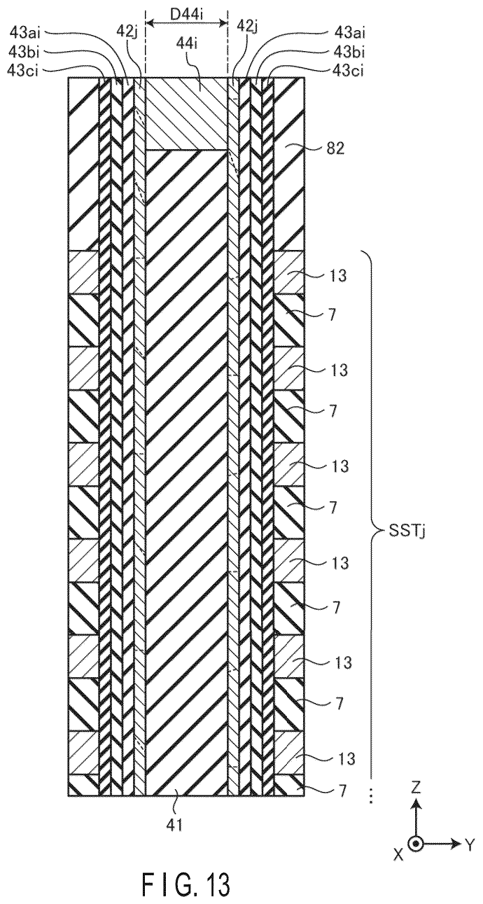

In FIG. 13, the polycrystalline semiconductor film 44i is buried in the recess 261. The polycrystalline semiconductor film 44i may be made of a material, the principal constituent of which is a polycrystalline semiconductor (for example, polysilicon) that includes an impurity (for example, phosphorous).

The XY-direction width D44i of the polycrystalline semiconductor film 44i corresponds to the average grain diameter d3. The XY-direction width D44i is larger than the film thickness D42j (see FIG. 11) and larger than the film thickness D42i (see FIG. 10). Correspondingly, the average grain diameter d3 is larger than the average grain diameter d1 and larger than the average grain diameter d2.

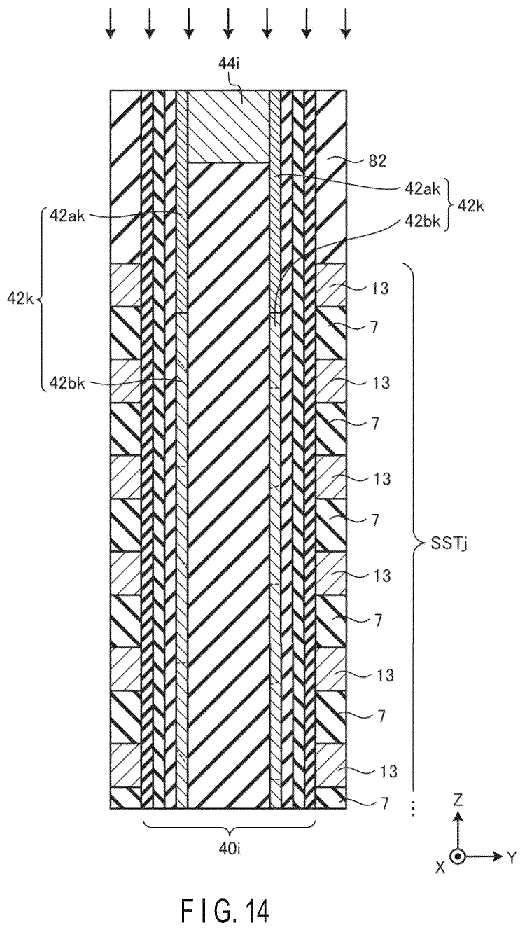

In FIG. 14, using a particle injection method or the like, predetermined particle types are introduced up to a predetermined Z-position in the polycrystalline semiconductor film 42j to make the section 42ak amorphous up to the predetermined Z-position in the polycrystalline semiconductor film 42k and leave the section 42bk that is deeper than the predetermined Z-position in a polycrystalline state without amorphization.

The introduced particles can be any particles suitable for producing amorphization. For example, the particles may be arsenic ions or argon molecules. The predetermined Z-position may be a Z-position between a Z-position of a +Z-side surface of the uppermost sacrificial layer 13 and a Z-position of a +Z-side surface of the second uppermost sacrificial layer 13. When the particle injection method is used, the Z-position (depth) for injection may be controlled, for example, by an acceleration voltage used in the particle injection process.

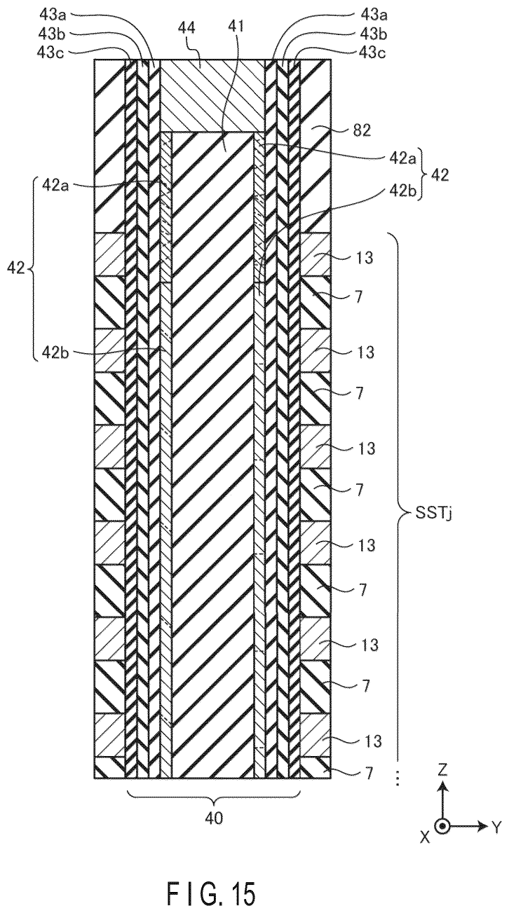

In FIG. 15, the columnar body 40i is subjected to heat treatment. Consequently, the section 42ak in an amorphous state in the polycrystalline semiconductor film 421 is crystallized, resulting in the side surface portion of the polycrystalline semiconductor film 44 and the section 42a of polycrystalline in the polycrystalline semiconductor film 42. The section 42bk of polycrystalline in the polycrystalline semiconductor film 421 remains substantially as it is as the section 42b of polycrystalline in the polycrystalline semiconductor film 42.

Here, in the section 42a, the average grain diameter becomes d1 depending on the film thickness D42j thereof (see FIG. 11) while being crystallized. The section 42b remains substantially the same and the average grain diameter remains as d2. The film thickness D42j is smaller than the film thickness D42i (see FIG. 10). Correspondingly, the average grain diameter d1 of the section 42a is smaller than the average grain diameter d2 of the section 42b.

The average grain diameter d3 of the polycrystalline semiconductor film 44 is larger than the average grain diameter d1 of the section 42a and larger than the average grain diameter d2 of the section 42b.

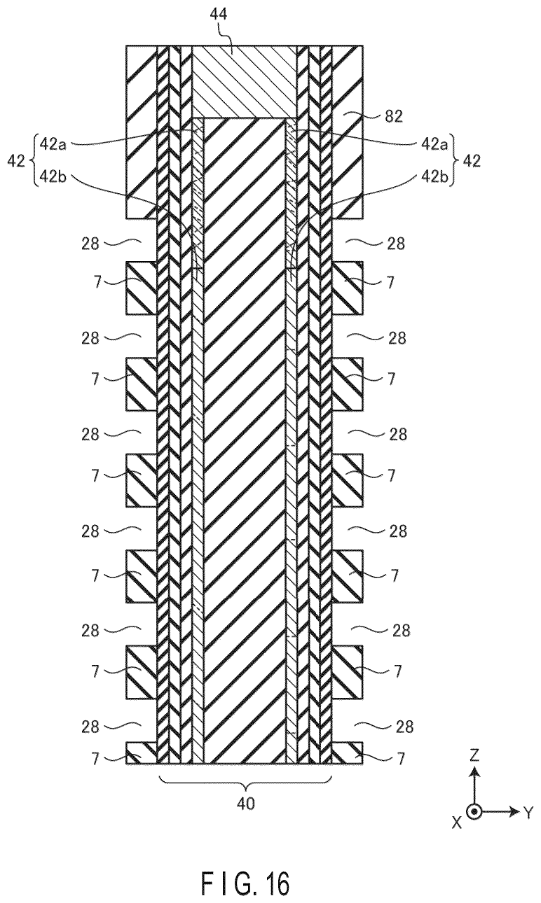

In FIG. 16, using isotropic etching such as wet etching, the sacrificial layer 13 in the laminate body SSTj is removed to form a gap 28. Then, an insulating film 8 (see FIG. 4) is formed to cover an exposed surface of the gap 28. The insulating film 8 may be formed of an insulator such as aluminum oxide.

In FIG. 4, a conducive material is buried in the gap 28 to form a conductive layer 6. The conductive layer 6 is formed of a material, the principal constituent of which is metal such as tungsten. In this way, the laminate body SST in which a plurality of insulating layers 7 and conductive layers 6 are laminated alternately is formed. That is, the semiconductor storage device 1 that includes the laminate body SST is formed.

As described above, in an embodiment, there is provided in the semiconductor storage device 1, the polycrystalline semiconductor film 42 that extends in the Z-direction in the laminate body SST in which the conductive layers 6 and the insulating layers 7 are laminated in an alternating and repetitive manner. In the polycrystalline semiconductor film 42, the average grain diameter d1 of section 42a corresponding to the uppermost conductive layer 6 on the +Z side (for example, the conductive layer 6 of the select gate SGDT 0) is smaller than the average grain diameter d2 of section 42b corresponding to the rest of the conductive layers 6 except for the uppermost layer (for example, the conductive layer 6 of the select gate SGDT1, the conductive layer 6 of the select gate SGD0, the conductive layer 6 of the select gate SGD1, . . . the conductive layer 6 of the select gate SGSB). Accordingly, the amount of diffusion of N-type impurities from the polycrystalline semiconductor film 44 to the section 42a and the section 42b can be properly controlled. As a result, efficient GIDL generation can be achieved at the select gate SGDT in a delete process and the select gate SGD can be properly turned on and off, so that the reliability of operation for the semiconductor storage device 1 can be improved.

For example, when the average grain diameter of the polycrystalline semiconductor film 42 is relatively large all along the film (for example, at the average grain diameter d2) from the +Z-side end to the −Z-side end, the diffusion length of N-type impurities from the polycrystalline semiconductor film 44 into the polycrystalline semiconductor film 42 tends to increase.

For a polycrystalline semiconductor film 42, the diffusion length of N-type impurities that diffuse across a grain boundary will be shorter than the diffusion length of N-type impurities that diffuse through just within a grain boundary. When the average grain diameter of the polycrystalline semiconductor film 42 is relatively large throughout its length (Z height dimension), the diffusion path tends to increase. In other words, the variation of the diffusion length of N-type impurities due to the difference in the diffusion paths tends to increase.

With changes in the Z-height of the core member 41, the tendency in diffusion length variations may be pronounced. For example, when the Z-height of the core member 41 is relatively long, the Z-distance from the +Z-side end of the core member 41 to the desired Z-position Zb (see the view (a) of FIG. 6) increases, which makes the impurity diffusion to the desired Z-position Zb difficult to achieve. When the Z-height of the core member 41 is relatively short, the Z-distance from the +Z-side end of the core member 41 to the desired Z-position Zb (see the view (a) of FIG. 6) is reduced, which makes the impurity diffusion to the desired Z-position Zb easier to achieve.

Due to the variation of the diffusion length of N-type impurities, the amount of diffusion of N-type impurities from the polycrystalline semiconductor film 44 to the polycrystalline semiconductor film 42 may be excessive.

In other words, as indicated by a dash-dot line in the view (a) of FIG. 6, in the polycrystalline semiconductor film 42, N-type impurities at or above the threshold concentration Cth will be present in the channel region of the select gate SGD. This may cause phenomena such as turning on of the select gate SGD even when it is not selected, which makes it difficult for the select gate SGD to properly turn on and off and leads to degradation of the reliability of operation of the semiconductor storage device 1.

Alternatively, due to the variation of the diffusion length of N-type impurities, the amount of diffusion of N-type impurities from the polycrystalline semiconductor film 44 to the polycrystalline semiconductor film 42 may be insufficient.

In other words, as indicated by a dotted line in the view (a) of FIG. 6, in the polycrystalline semiconductor film 42, N-type impurities are below the threshold concentration Cth in the channel region of the select gate SGDT. This may lead to insufficient GIDL generation at the select gate SGDT in the delete process, which makes it difficult to properly perform the delete process and leads to degradation of the reliability of operation of the semiconductor storage device 1.

On the other hand, in the present embodiment, the average grain diameter d1 the section 42a in the polycrystalline semiconductor film 42 is smaller than the average grain diameter d2 of the section 42b. Accordingly, the amount of diffusion of N-type impurities from the polycrystalline semiconductor film 44 to each of the section 42a and the section 42b can be properly controlled.

In the polycrystalline semiconductor film 42, the effects of the variation of the diffusion path can be reduced. In other words, the ratio of N-type impurities that diffuse through within particles to N-type impurities that diffuse through the grain boundary decreases, and the variation of the diffusion length of N-type impurities due to the difference in the diffusion paths can be reduced. In this way, the effect of the variation of the Z-height of the core member 19 can be reduced.

For example, as indicated by a solid line in the view (a) of FIG. 6, in the polycrystalline semiconductor film 42, N-type impurities are included in the channel region of the select gate SGDT at or above the threshold concentration Cth, while N-type impurities are below the threshold concentration Cth in the channel region of the select gate SGD. As a result, efficient GIDL generation can be achieved at the select gate SGDT in the delete process and the select gate SGD can be properly turned on and off, so that the reliability of operation of the semiconductor storage device 1 can be improved.

Note that, as a modification in the manufacturing of the semiconductor storage device 1, the step in which the polycrystalline semiconductor film 42j is made partially amorphous and the step in which the polycrystalline semiconductor film 44i is buried in the recess 261 may be swapped with each other.

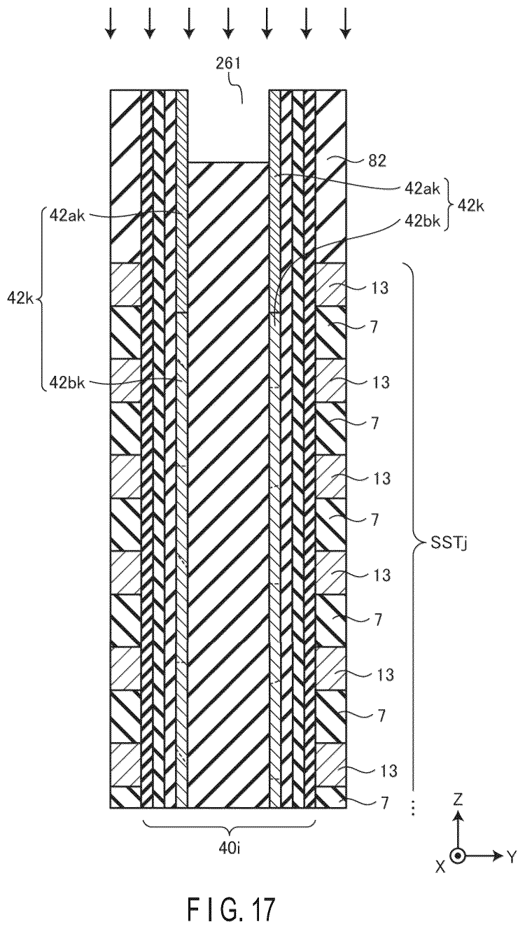

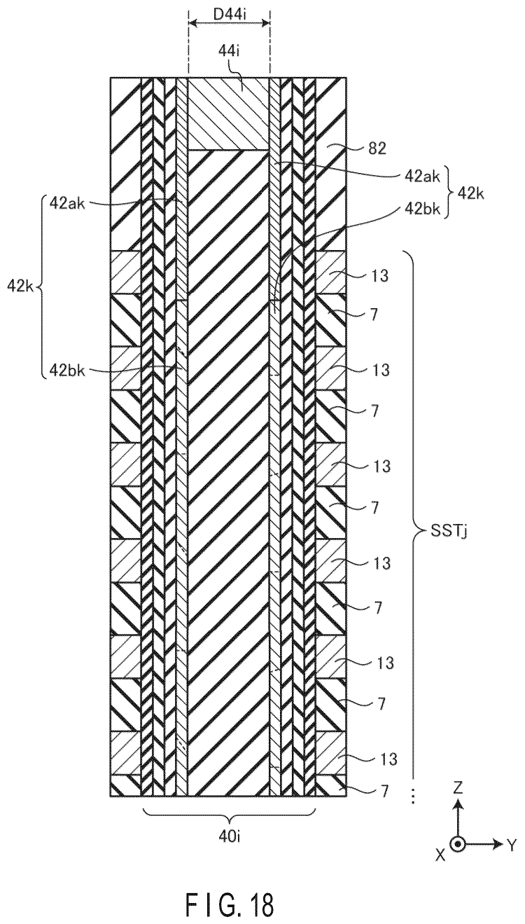

For example, processes illustrated in FIGS. 17 and 18 may be performed in place of the processes illustrated in FIGS. 13 and 14. Each of FIGS. 17 and 18 is a YZ-sectional view illustrating a manufacturing method of a semiconductor storage device 1 according to a modification.

After the steps illustrated in FIGS. 7 to 12 have been performed as already described, the step illustrated in FIG. 17 is performed. In FIG. 17, a particle injection method or the like is used and particles are introduced up to a predetermined Z-position in the polycrystalline semiconductor film 42j to make the section 42ak amorphous up to the predetermined Z-position in the polycrystalline semiconductor film 42k and leave a section 42bk that is deeper than the predetermined Z-position in a polycrystalline state without amorphization.

The particles may be any particles suitable for amorphization. For example, the particles used here may be arsenic ions argon molecules. The predetermined Z-position may be a Z-position between a Z-position of a +Z-side surface of the uppermost sacrificial layer 13 and a Z-position of a +Z-side surface of the second uppermost sacrificial layer 13. When a particle injection method is used, the Z-position (injection depth) may be controlled by an acceleration voltage used in the particle injection process.

In FIG. 18, the polycrystalline semiconductor film 44i is buried in the recess 261. The polycrystalline semiconductor film 44i may be made of a material, the principal constituent of which is a polycrystalline semiconductor (for example, polysilicon) that includes an impurity (for example, phosphorous).

The XY-direction width D44i of the polycrystalline semiconductor film 44i corresponds to the average grain diameter d3. The XY-direction width D44i is larger than the film thickness D42j (see FIG. 11) and larger than the film thickness D42i (see FIG. 10). Correspondingly, the average grain diameter d3 is larger than the average grain diameter d1 and larger than the average grain diameter d2.

Thereafter, the steps illustrated in FIG. 15 and subsequently are performed.

According to this manufacturing method, a semiconductor storage device 1 that includes a polycrystalline semiconductor film 42 in which the average grain diameter d1 of the section 42a is smaller than the average grain diameter d2 of the section 42b can also be manufactured.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor storage device, comprising:
a laminated body on a substrate, the laminated body comprising conductive layers alternating with insulating layers in a first direction;
a column extending into the laminated body in the first direction, the column including:
a first polycrystalline semiconductor film extending along the column in the first direction; and
a first insulating film extending along the column in the first direction, the first insulating film being between the conductive layers and the first polycrystalline semiconductor film, wherein
the first polycrystalline semiconductor film includes:
a first section corresponding in position along the first direction to a first conductive layer among the conductive layers in the laminated body that is a farthest layer from the substrate in the first direction; and
a second section between the first section and the substrate in first direction, and
an average grain diameter of the first section is smaller than an average grain diameter of the second section.

2. The semiconductor storage device of claim 1, wherein a boundary between the first section and the second section is located at a position between a position of an upper surface of the first conductive layer and a position of an upper surface of another one of the conductive layers among the conductive layers in the laminated body.

3. The semiconductor storage device of claim 2, wherein the position of the boundary between the first section and the second section is substantially equal to a position of a lower surface of the first conductive layer.

4. The semiconductor storage device of claim 1, wherein the column further includes:
an insulating core extending in first direction, the first polycrystalline semiconductor film being between the insulating core and the conductive layers.

5. The semiconductor storage device of claim 4, further comprising:
a second polycrystalline semiconductor film that covers an upper end of the first polycrystalline semiconductor film and an upper end of the insulating core, wherein
the second polycrystalline semiconductor film includes a dopant.

6. The semiconductor storage device of claim 5, wherein the dopant is phosphorus.

7. The semiconductor storage device of claim 5, wherein the average grain diameter of the first section is smaller than an average grain diameter of the second polycrystalline semiconductor film.

8. The semiconductor storage device of claim 5, wherein
a diffusion distance of the dopant in the first direction from the second polycrystalline semiconductor film is substantially equal to a distance in the first direction from the boundary to an interface that is between the second polycrystalline semiconductor film and the first polycrystalline semiconductor film.

9. A semiconductor storage device, comprising:
a laminated body on a substrate, the laminated body comprising conductive layers alternating with insulating layers in a first direction;
a column extending into the laminated body in the first direction, the column including:
a first semiconductor film extending along the column in the first direction; and
a first insulating film extending along the column in the first direction, the first insulating film being between the conductive layers and the first semiconductor film, wherein
the first semiconductor film includes:
a first section corresponding in position along the first direction to a first conductive layer among the conductive layers in the laminated body that is a farthest layer from the substrate in the first direction; and
a second section between the first section and the substrate in first direction, and
an average grain diameter of the first section is smaller than an average grain diameter of the second section.

10. The semiconductor storage device of claim 9, wherein
the first section is polycrystalline semiconductor material, and
the second section is polycrystalline semiconductor material.

11. The semiconductor storage device of claim 9, wherein
the first section is amorphous semiconductor material, and
the second section is polycrystalline semiconductor material.

12. The semiconductor storage device of claim 11, wherein a boundary between the first section and the second section is located at a position between a position of an upper surface of the first conductive layer and a position of an upper surface of another one of the conductive layers among the conductive layers in the laminated body.

13. The semiconductor storage device of claim 12, wherein the position of the boundary between the first section and the second section is substantially equal to a position of a lower surface of the first conductive layer.

14. The semiconductor storage device of claim 11, wherein the column further includes:
an insulating core extending in the first direction, the first semiconductor film being between the insulating core and the conductive layers.

15. The semiconductor storage device of claim 14, further comprising:
a second semiconductor film that covers an upper end of the first semiconductor film and an upper end of the insulating core, wherein
the second semiconductor film includes a dopant.

16. The semiconductor storage device of claim 15, wherein the dopant is phosphorus.

17. The semiconductor storage device of claim 15, wherein the second semiconductor film is polycrystalline.

18. The semiconductor storage device of claim 15, wherein
a diffusion distance of the dopant in the laminate first direction from the second semiconductor film is substantially equal to a distance in the first direction from the boundary to an interface that is between the second polycrystalline film and the first semiconductor film.

19. A semiconductor storage device, comprising:
a laminated body on a substrate, the laminated body comprising conductive layers alternating with insulating layers in a first direction;
a plurality of columns extending into the laminated body in the first direction, each column including:
a first polycrystalline semiconductor film extending along the column in the first direction; and
a first insulating film extending along the column in the first direction, the first insulating film being between the conductive layers and the first polycrystalline semiconductor film, wherein
the first polycrystalline semiconductor film includes:
a first section corresponding in position along the first direction to a first conductive layer among the conductive layers in the laminated body that is a farthest layer from the substrate in the first direction; and
a second section between the first section and the substrate in the first direction, and
an average grain diameter of the first section is smaller than an average grain diameter of the second section.

20. The semiconductor storage device of claim 19, wherein a boundary between the first section and the second section is located at a position between a position of an upper surface of the first conductive layer and a position of an upper surface of another one of the conductive layers among the conductive layers in the laminated body.
